(19) United States
(12) Patent Application Publication
(10) Pub. No.: US 2010/0128433 A1
(43) Pub. Date: May 27, 2010

(54) Cap for Electronics Enclosure

(75) Inventors: Walter Harwood, Streamwood, IL (US); Albert F. McGovern, JR., Naperville, IL (US); Chris Cutaia, Webster, NY (US)

Correspondence Address: LEYDIG VOIT & MAYER, LTD, TWO PRUDENTIAL PLAZA, SUITE 4900, 180 NORTH STETSON AVENUE, CHICAGO, IL, 60601-6731, US

(73) Assignee: Charles Industries, Ltd., Rolling Meadows, IL (US)

(21) Appl. No.: 12/276,234

(22) Filed: Nov. 21, 2008

(51) Int. Cl. H05K 7/20; H05K 7/00

(52) U.S. Cl. 361/690; 361/679.01

(57) ABSTRACT

A pedestal style electronics enclosure provides an upright housing for enclosing electronic components. Installed at the top of the housing can be a hollow enclosure cap that defines an internal air gap. The air gap can be located between an upper, dome-like shield plate exposed to the exterior and a lower, contoured guide plate exposed to the interior of the enclosure. The air gap can help buffer the enclosure from solar radiation impinging upon the exterior shield plate. The interior contoured guide plate can help direct heated air rising in the interior of the enclosure to one or more vent panels located about the periphery of the cap. The hollow enclosure cap can be comprised of thermoplastic material and can be made as a single piece, monolithic structure produced by, for example, a blow molding process.

### BACKGROUND OF THE INVENTION

In the telecommunications and electrical transmission industry, there are various different types of enclosures for housing and protecting electronic equipment such as switches, connectors and/or splices. The enclosed electronic equipment may be in communication with data transmission lines or cables that can be directed into the enclosure. In some instances, these enclosures are designed for placement outdoors. Such outdoor enclosures must protect the electronic equipment from environmental concerns such as precipitation as well as from tampering by humans and/or animals.

The electronics equipment housed in outdoor enclosures often produces its own heat. Accordingly, the enclosures used with such heat-producing equipment should be designed to remove this heat to keep the enclosed equipment within safe operating temperatures. One way in which this may be accomplished is by including vents on the enclosure that vent the heat to the surrounding environment. The vents are typically located near the top of the enclosure so that heated air rising within the enclosure will exhaust through the vents.

Locating the enclosure outdoors may also expose the top of the pedestal to solar radiation such as sunlight which may harmfully raise the temperature of the enclosure. Accordingly, it would be advantageous to have a pedestal style enclosure that provides venting of the enclosure interior while resisting harmful temperature increases due to solar radiation.

### BRIEF SUMMARY OF THE INVENTION

The invention provides an electronics enclosure that may be in the form of a pedestal style enclosure and that may include a cap designed to help prevent excessive heat from building-up in the enclosure. The cap, which is installed on the top of the pedestal, can be a hollow structure that includes an internal void or air chamber. In particular, the cap can include an upper shield plate that is joined to a lower guide plate so that an air gap is formed between the two plates. When installed on an enclosure, the upper shield plate will be exposed on the top of the enclosure while the lower guide plate is exposed to the interior. If the enclosure is located outdoors, solar radiation may impinge upon the upper shield plate of the cap tending to raise the temperature of the enclosure. The air gap provided between the upper shield plate and the lower guide plate may act as an additional buffer helping to prevent the solar-induced heat from being transferred to the interior of the enclosure.

In addition, the guide plate of the cap may be shaped or contoured to improve the venting of heat from the interior of the enclosure. The cap can be installed on the top of a pedestal style enclosure so that the guide plate is exposed to the interior. To provide the vents, the cap can include one or more vent panels that are offset or spaced apart from the wall of the pedestal housing on which the cap is installed. The lower guide plate may be contoured to have a drooping center point protruding towards the interior of the enclosure and to have arch-like lobes curving upwardly and outwardly toward the vent panels. As the enclosed electronics heat the air in the interior of the enclosure, the heated air can rise inside the pedestal housing and encounter the guide plate where the contours direct the heated air to the vents formed by the offset vent panels.

The cap can be made from molded thermoplastic material. Preferably, the cap can be made as a single, monolithic part by a blow molding process. In this process, a blank or preform of thermoplastic material is placed between two opposing mold walls. Pressurized air may be injected into the blank causing the blank to inflate against the opposing mold walls and assume the shape of the mold walls. The resulting part is the hollow cap with an internal air gap between the upper and lower plates. Further, one of the mold walls may correspond to the contoured guide plate so as to accordingly shape the inflated blank.

A possible advantage of the disclosed enclosure cap is that the air gap helps compensate for solar radiation impinging on the enclosure. Another possible advantage is that the contoured shape of the lower guide plate helps direct heated air from the interior toward the vents. These and other advantages and features will become apparent from the accompanying detailed description and the drawings.

### BRIEF DESCRIPTION OF THE DRAWINGS

FIG. 1 is a perspective view of an exemplary pedestal type electronics enclosure such as commonly used in telecommunications and electrical transmission.

FIG. 2 is a cross sectional view taken along line 2-2 of FIG. 1 illustrating the interior of the pedestal enclosure with an exemplary enclosure cap installed on the top end of the pedestal enclosure.

FIG. 3 is a top perspective view of the enclosure cap removed from the main housing of the enclosure illustrating the upper shield plate.

FIG. 4 is a bottom perspective view of the enclosure cap illustrating the contoured lowered guide plate.

FIG. 5 is a perspective assembly view of the hollow enclosure cap illustrating the upper shield plate removed from the lower guide plate.

FIG. 6 is a top plane view of the enclosure cap taken primarily of the upper shield plate.

FIG. 7 is a cross-sectional view taken along line 6-6 of FIG. 5 illustrating the air gap formed between the upper shield plate and the lower guide plate of the enclosure cap and particularly illustrating the drooping center point of the lower guide plate.

FIG. 8 is a cross-sectional view taken along line 7-7 of FIG. 5 illustrating the air gap formed between the upper shield plate and the lower guide plate of the enclosure cap and particularly illustrating the depending troughs of the lower guide plate.

FIG. 9 is a cross-sectional view taken along line 8-8 of FIG. 5 illustrating the air gap formed between the upper shield plate and the lower guide plate and particularly illustrating the joinder of the upper shield plate and lower guide plate.

FIG. 10 is a perspective view of another embodiment of a pedestal style electronics enclosure that is cylindrical in shape.

FIG. 11 is a cross sectional view taken along line 11-11 of FIG. 10 illustrating the interior of the cylindrical enclosure which includes a circular enclosure cap positioned on the top end of the pedestal enclosure housing.

FIG. 12 is a top perspective view of the circular enclosure cap removed from the housing of the enclosure illustrating the dome-like upper shield plate.

FIG. 13 is a bottom perspective view of the circular enclosure cap illustrating the contoured shape of the inner guide plate of the cap.

FIG. 14 is a top plane view of the circular enclosure cap.

FIG. 15 is a perspective assembly view of the circular enclosure cap illustrating an upper shield plate removed from the lower guide plate.

FIG. 16 is a cross sectional view taken along line 16-16 of FIG. 14 illustrating an air gap formed between the upper shield plate and the lower guide plate of the circular enclosure cap.

### DETAILED DESCRIPTION

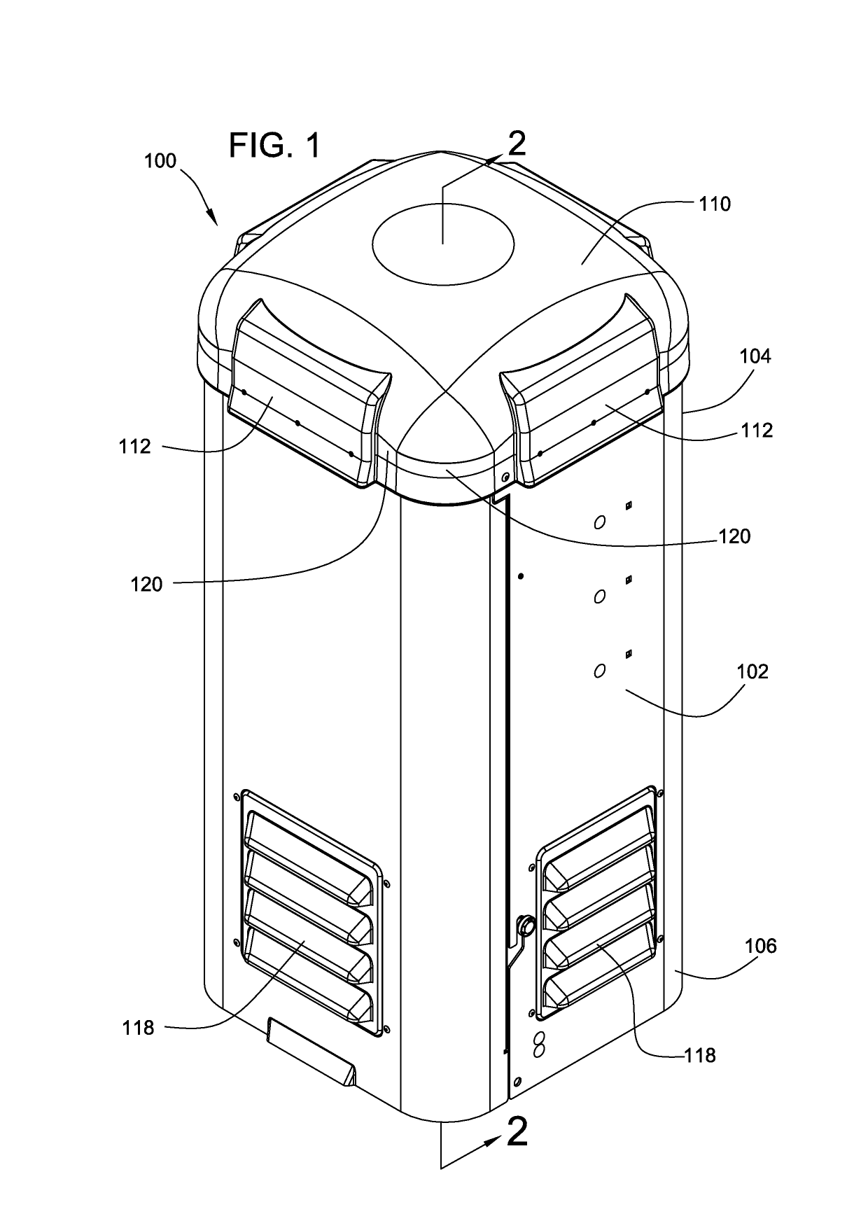

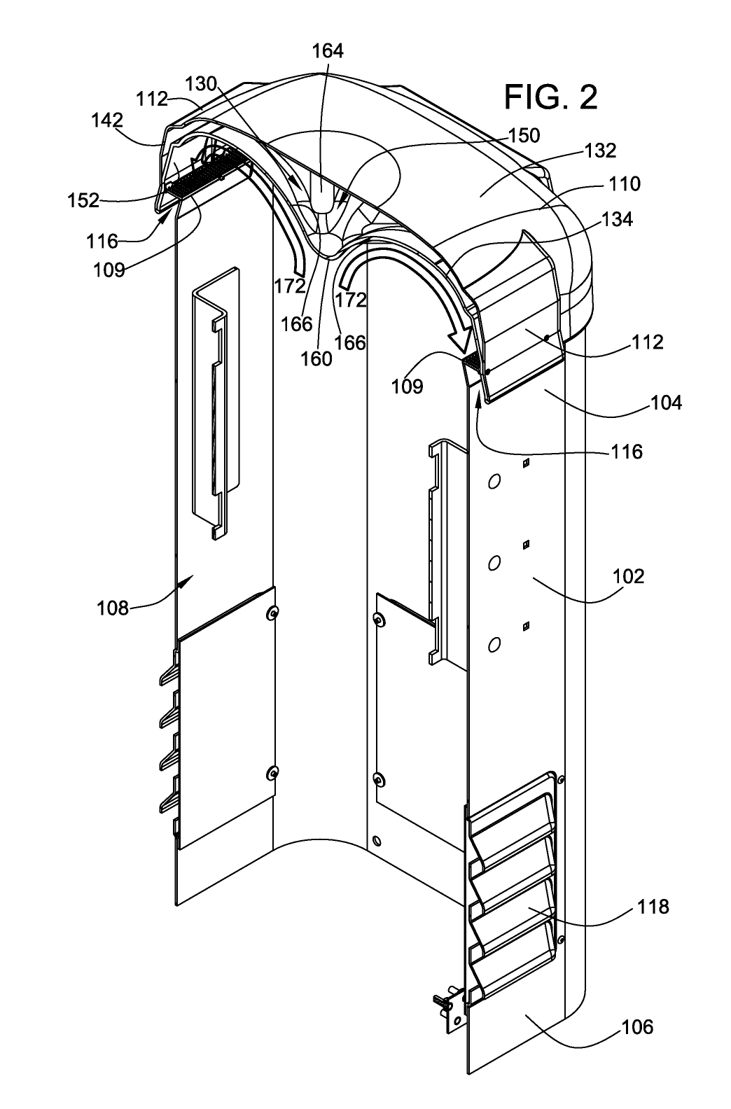

Now referring to the drawings, wherein like reference numbers refer to like elements, there is illustrated in FIGS. 1 and 2 an exemplary pedestal-style electronics enclosure 100 intended for outdoor service. The enclosure 100 can include a generally upright, mast-like main body or housing 102. In the illustrated embodiment, the housing 102 can be in the shape of an elongated, open-ended rectangle with a top end 104 and an opposing bottom end 106. The rectangular housing can have a square cross-section, but in other embodiment can have other suitable shapes including circular. Furthermore, it should be noted that terms such as “top,” “bottom,” “upper,” “lower,” and the like are meant only to provide reference and are not to be construed as a limitation on the claims. The housing 102 can be made from formed sheet metal, molded plastic or any other suitable material. Referring to FIG. 2, the interior 108 of the housing 102 is generally open space inside of which various switches, connectors, terminals and other electronic equipment can be located. The bottom end 106 of the housing 102 can provide an opening into which telecommunications lines or cables can be directed. In other embodiments, the lower end 104 can be generally closed with punch-outs or ports through which lines and cables can be directed.

In some installations, the bottom end 106 of the housing 100 can be attached to a base that may be partially or completely buried underground. The housing can be located above and rise upwards from the ground. Underground cables or lines can be directed into and through the base and upwards through the opening at the bottom end 106. The cable or lines can then be directed through the interior 108 to the electronics equipment, the vertical position of which is preferably above ground. Service technicians can access the above-ground electronic equipment by detaching and lifting up the housing 102 from the base, without otherwise having to unbury the base portion of the enclosure. In other embodiments, the pedestal style housing can be set on a concrete pad or floor.

A cap 110 is located at the top end 104 of the enclosure housing 102. In the illustrated embodiment, the cap 110 is a square, generally-box like structure that can be installed over and sit on a rim 109 of the open top end 104. To match the square cross-section of the housing 102, the box-like cap 110 can likewise be square and have four interconnected, orthogonally arranged sides 120. However, in other embodiments, the cap can have other shapes and designs such as rectangular or circular. The cap 110 can give the pedestal enclosure 100 an approximately flattop appearance.

To remove the heated air from the interior of the enclosure such as the air that may be heated by the electronic components, the cap 110 can be configured to provide one or more vents. In pedestal-style enclosures, the upright pedestal design can produce a chimney effect in which the heated air inside the enclosure rises up the elongated housing toward the cap and exhausts out the vents. The rise of the heated air can also help draw cooler air from the surrounding environment into the enclosure through a location proximate the bottom end of the housing. The circulating air through the enclosure can help keep the electronic equipment cool. To facilitate the chimney effect, it is desirable to locate the exhaust vents near the top of the enclosure and the intake vents near the bottom end.

Referring to FIGS. 1 and 2, to form the exhaust vents, the cap 110 can include one or more offset vent panels 112. In the illustrated embodiment, a rectangular vent panel 112 can protrude from each of the four sides 120 so that the assembled enclosure will have four exhaust vents. The vent panels 112, which in the illustrated embodiment are rectangular in shape, protrude or bulge outwardly from the sides 120 of the box-like cap 110. When installed on the enclosure housing, the vent panels are offset with respect to or spaced apart from the uppermost rim 109 of the housing 102 and thus provide a clearance 116 between the vent panel and the housing sidewall. The clearance 116 is in communication with the interior 108 of the enclosure and allows the rising heated air to escape to the surrounding environment.

To draw cooler environmental air into the enclosure and facilitate the chimney effect, the lower end 106 of the housing can include one or more open intake vents 118 communicating with the interior 108. To inhibit rain or other precipitation from entering the enclosure 100 through the vents, the offset vent panels 112 can be arranged so that the clearances 116 are directed generally downwards. Additionally, it is desirable to make the clearances as narrow as possible to prevent insects and other foreign objects from entering the enclosure. Screens or mesh may also be installed in the clearances 116 to prevent foreign objects from entering the enclosure. Additionally, the illustrated intake vents 118 may also be directed downwardly and include screens or mesh.

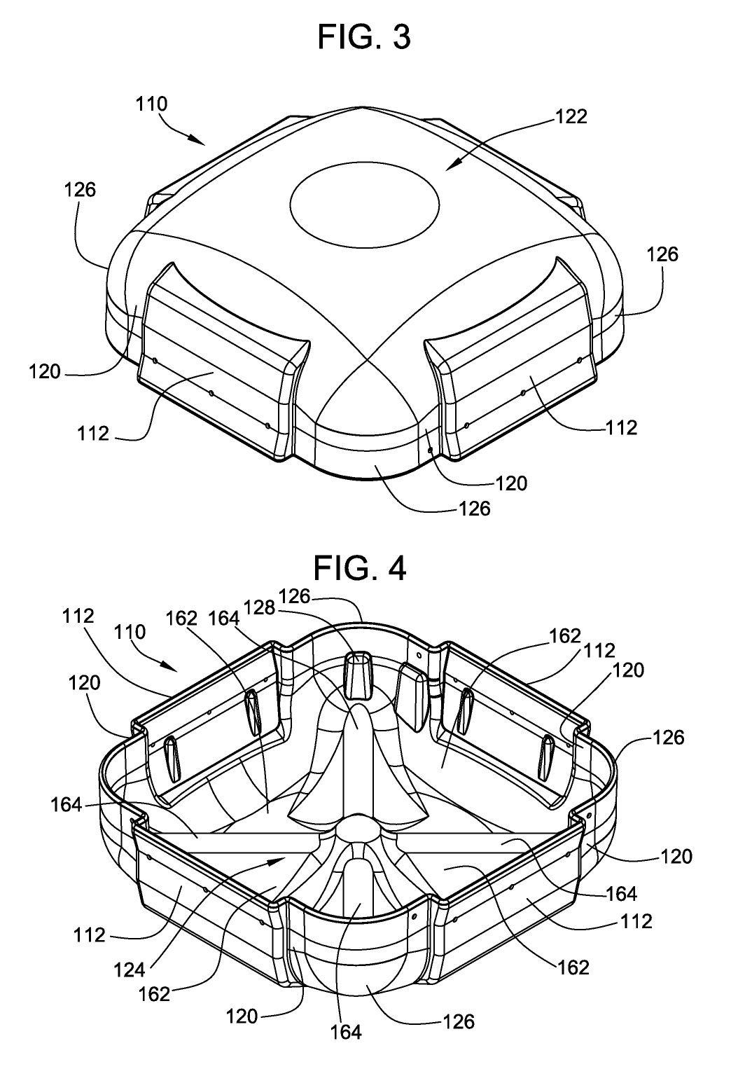

Referring to FIGS. 3, 4 and 5, and as mentioned above, the enclosure cap 110 can have a generally box-like structure with four orthogonally arranged, interconnected sides 120. The exterior surface 122 of the cap 110, which is intended to be exposed to the surrounding environment, may have a smooth, generally dome-like shape while the inner surface 124, which is intended to be exposed to the interior of the enclosure, may have a contoured shape, the particular details of which will be described below. Additionally, one or more inward projecting bosses 128 may be formed proximate each of the four corners 126 of the cap. As can be appreciated, when the cap is installed on the top end of the housing, the bosses 128 can rest a top the uppermost rim 109 of the housing.

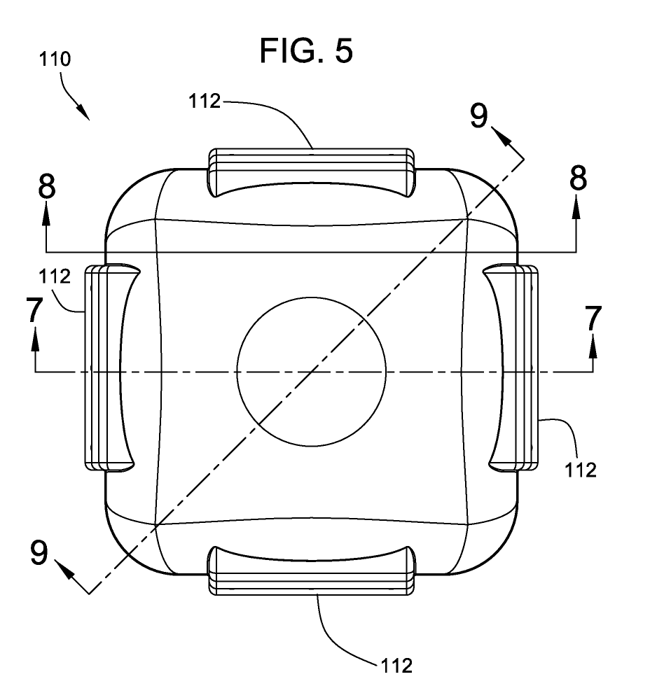

Referring to FIGS. 5, 6 and 7, in accordance with one aspect of the disclosure, the enclosure cap 110 can be formed as a hollow structure having an internal void or air gap 130, which may assist in moderating the temperature of the enclosure 100. The internal air gap 130 can be substantially enclosed within and confined by the cap structure. When the cap 110 is installed on the top of an outdoor pedestal enclosure, solar radiation such as sun light can impinge upon the cap. The air gap 130 within the hollow cap 110 may absorb some of the heat associated with the impinging sunlight and can thereby function as a buffer that insulates the heat from the rest of the enclosure.

In the illustrated embodiment, the enclosure cap 110 includes an upper shield plate 132 and a lower guide plate 134 that are joined together and in between which is delineated the air gap 130. As can be appreciated, the upper shield plate corresponds to the dome-like exterior surface 122 in FIGS. 3, 4 and 5, and the lower guide plate 134 corresponds to the contoured inner surface 124. In this case, the upper shield plate 132 defines a dome-like structure that includes a generally planar central portion 140 and a depending peripheral wall 142 that extends downward from the periphery of the planar central portion. Like the overall, generally square, enclosure cap 110, the depending wall 142 can have four interconnected, orthogonally arranged sides or edges. The lower guide plate 134 also includes a second central portion 150 and a second depending peripheral wall 152 that also can have four interconnected, orthogonal sides or edges. The vent panels 112 can be formed as rectangular surfaces that are offset or project outwardly from the sides or edges of the first and second depending peripheral walls 142, 152 of the respective upper shield plate 132 and lower guide plate 134.

To help direct heated air out of the enclosure through the vents, the central portion 150 of the lower guide plate 134, unlike the planar central portion 140 of the upper shield plate 132, can have a contoured shape. When the lower guide plate 134 is joined to the upper shield plate 132, the contoured shape can provide an internal cavity forming the air gap 130. In the illustrated embodiment, the contoured portion 150 has a depending or drooping shape in which the contoured portion extends from the upper edge of all four sides of the peripheral wall 152 and curves or arcs inward and downward so as to form a cusp-like drooping center point 160 located generally at the center of the lower guide plate. In this case, the drooping center point 160 extends downward to a location below the upper edges of the peripheral wall 152 from which the contoured portion 150 extends.

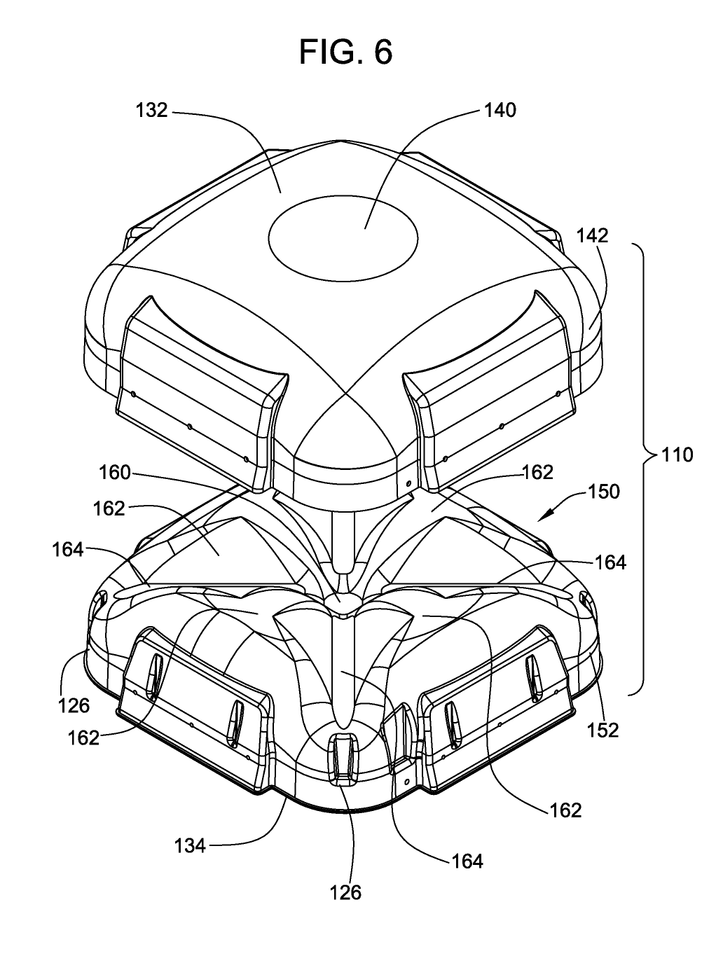

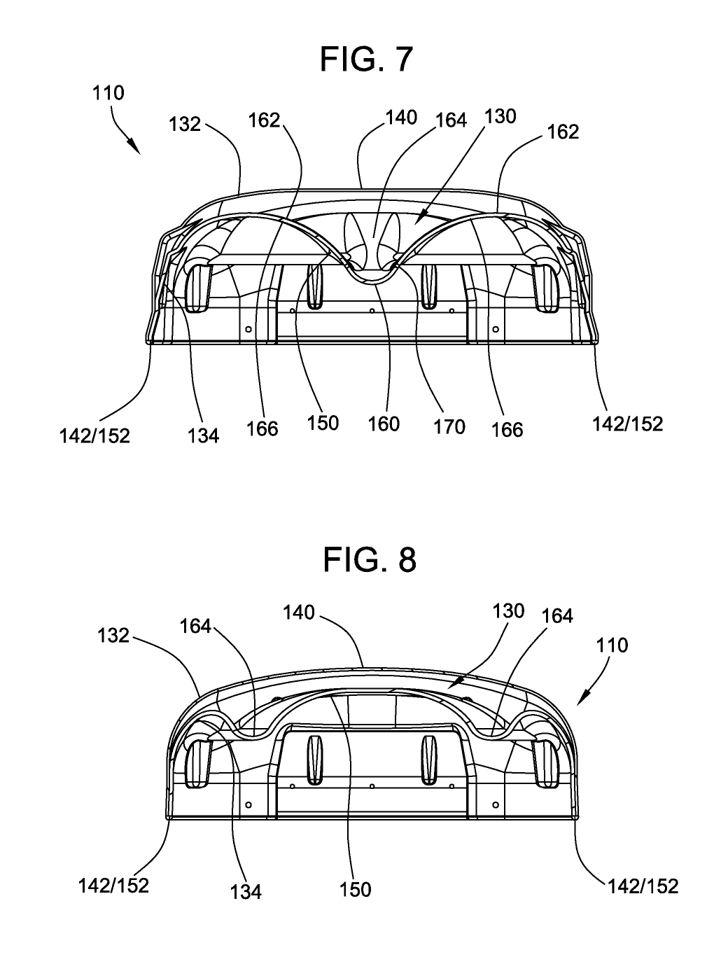

In the present embodiment, as illustrated best in FIGS. 6 and 7, the contoured central portion 150 further includes four separate curving surfaces or lobes 162 each of which are associated with one of the four sides of the peripheral wall 152. The lobes 162 can curve or arc to intersect together in a cusp that is the drooping center point 160. The illustrated contoured portion 150 also includes four depressed troughs 164 that extend inwardly from each of the four corners 126 of the lower guide plate 134 and intersect at the drooping center point 160. As illustrated best in FIGS. 4 and 6, the troughs 164 generally form a cross within the generally square lower guide plate 134 and can partition the four lobes 162 into distinct, generally triangular shapes.

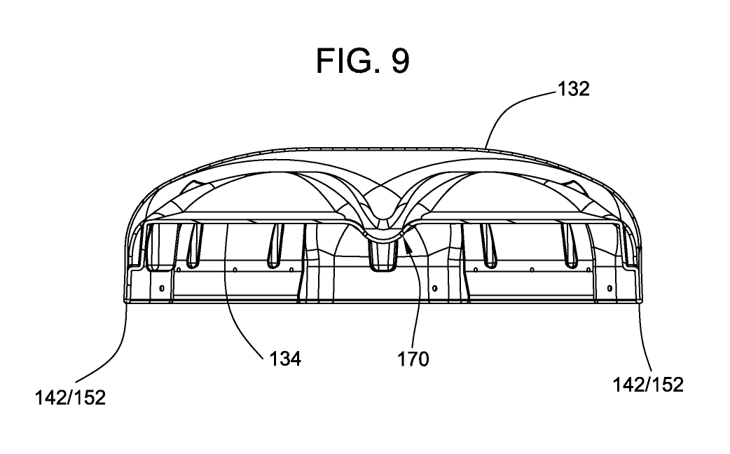

Referring to FIGS. 7, 8 and 9, the contoured portion 150 provides the lower guide plate 134 with a vault-like appearance including, at a location corresponding to the horizontal midline of the enclosure cap 110, curved arches 166 corresponding to the contoured lobes 162 that intersect at the drooping center point 160. When the lower guide plate 134 and upper shield plate 132 are joined together, the lower guide plate can be received within and accommodated by the upper guide plate such that the first and second depending peripheral walls 142, 152 can be in adjacent contact with each other. As illustrated, the first depending peripheral wall 142 of the upper shield plate 132 generally surrounds and holds the second depending peripheral wall 152 of the lower guide plate 134. However, the overall contour of the contoured portion 150 including the curved arches 166 and the cusp-like drooping center point 160 partially separates and spaces the lower guide plate from the generally planar central portion 140 of the upper shield plate 132. Hence, the drooping center point 160 and the troughs 164 assist in defining the internal cavity that serves as the air gap 130.

Referring back to FIG. 2, when the cap 110 is installed on a pedestal-style enclosure 100, the upper shield plate 132 is exposed to the environment and can be made of a material or with a color that deflects some of the impinging solar radiation. The lower guide plate 134 is exposed to the interior of the enclosure 100 and generally separates the air gap 130 from the interior and electronic components located therein. Accordingly, the air gap 130 is positioned to further buffer or insulate the interior 108 of the enclosure from solar radiation. In an embodiment, the air gap 130 can be sealed off from the outside environmental air. Referring to FIGS. 7, 8 and 9, this can be accomplished by placing the first and second depending peripheral sidewalls 142, 152 in continuous contact about the entire periphery of the cap 110. The contiguous peripheral sidewalls 142, 152 seal the air gap 130 from the exterior of the enclosure. In another embodiment, to allow for thermal expansion of heated air within the air gap 120, the lower guide plate 124 can include one or more small holes 170 that establish communication between the air gap and the interior of the enclosure 100. The expanding heated air in the air gap 130 can move into the interior of the enclosure, thereby reducing pressure buildup within the air gap. As can be appreciated, in this embodiment, allowing for thermal expansion of air within the air gap can help prevent damage to the enclosure cap. Even considering the holes 170, it will be appreciated that the air gap 130 may remain substantial confined by the cap structure and substantially separated from the interior of the enclosure.

In another aspect of the disclosure, the contour of the lower guide plate 134 can facilitate the chimney effect of the pedestal-style enclosure 100. Specifically, the interrelation of the curves and arcs of the interior surface of the lower guide plate can function to direct hot air from the interior volume toward the exhaust vents. Referring back to FIG. 2, the interior surface of the contoured central portion 150 of the lower guide plate 134 is exposed to the interior 108 of the enclosure 100 when the cap 110 is installed on the top of the pedestal enclosure. The drooping center point 160 and the four troughs 164 depend downwardly toward the interior 108 while the curved arches 166 corresponding to the lobes arc upwardly and outwardly to the offset vent panels 112 formed into the depending peripheral sidewalls 142, 152. As heated air from the interior 108 of the enclosure 100, indicated by arrows 172, rises up the pedestal and encounters the guide plate 134, the arches 166 can direct the rising air outwardly toward the vent panels 112 and back down out the clearances 116. Hence, the lower guide plate functions as a guide or deflector to the heated air. As can be appreciated, this facilitates the circulation of air through the enclosure. The heated air being directed along the arches 166 can encounter and carry outwardly to the vents the heated air from the gap 130 that moves into the interior 108 through holes disposed in the lower guide plate because of thermal expansion. In various embodiments, the interior surface of the lower guide plate can be metalized or otherwise treated to improve its heat resistance properties.

In another aspect of the disclosure, the enclosure cap can be of a monolithic or single piece construction. In such a monolithic cap, the upper shield plate and the lower guide plate are formed from the same part and need not be joined by fasteners or adhesive. A preferred method of producing such a monolithic cap is through a double walled, blow molding process. In this process, a thermoplastic blank or pre-form is placed between two mold walls, one of which has a shape corresponding to the upper shield plate and the other of which has a shape corresponding to the lower guide plate. The thermoplastic blank may then be heated and pressurized air can be injected from a needle into the pre-form causing it to inflate against the walls of the mold thus taking the shape of the mold. As can be appreciated from FIGS. 6, 7, and 8, the inflated interior of the blank can correspond to the air gap 130 while the layers of the blank pressed against the mold walls correspond to the upper shield plate 132 and the lower guide plate 134. The molded plastic part is then ejected from the mold and can be subjected to further processing or treating steps. Other manufacturing methods for producing a monolithic cap include a 2-shot injection molding process and the co-extrusion of plastic material together.

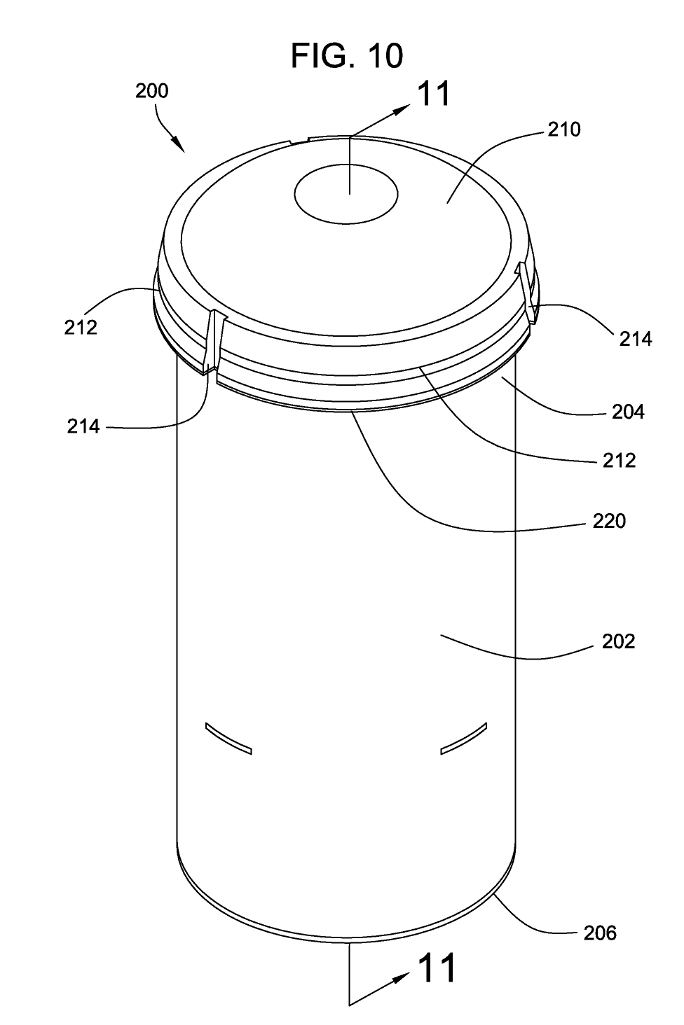

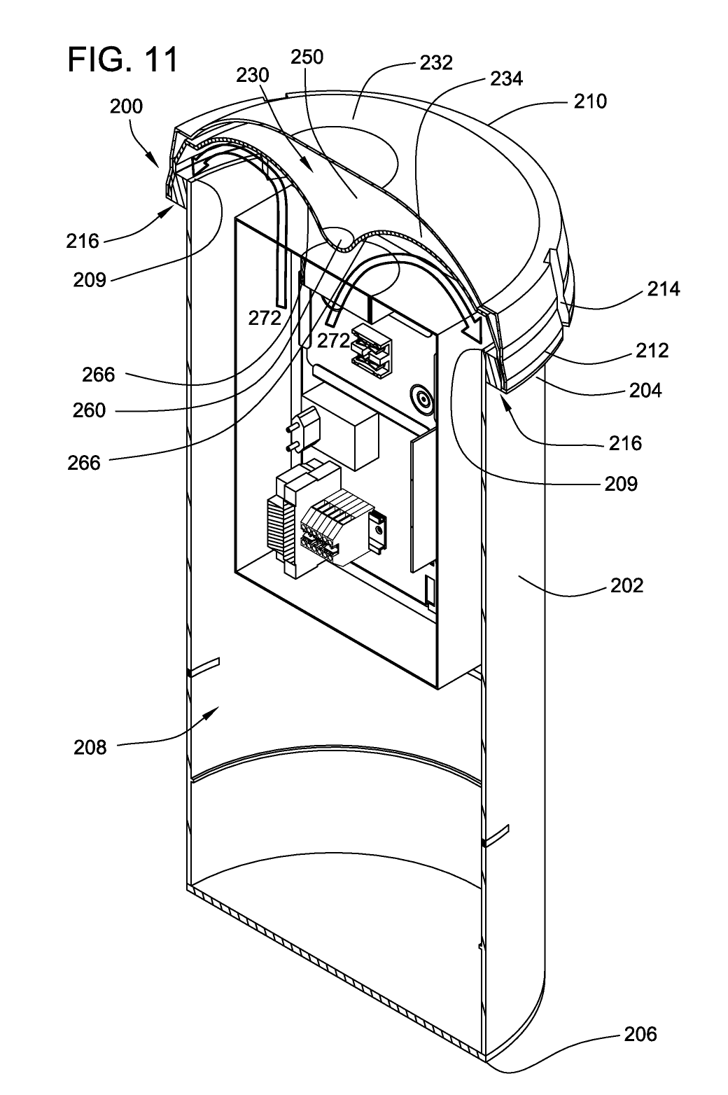

Referring to FIGS. 10 and 11, there is illustrated another embodiment of a pedestal style electronics enclosure 200 which is shaped as an elongated, upright cylinder. The enclosure 200 can include a circular, canister-like housing 202 with an open top end 204 and a closed bottom end 206 that defines an interior volume 208 in which the electronic devices can be housed. To enclose the interior 208, there is positioned on the top end 204 of the housing 202 an enclosure cap 210. To match the cylindrical shape of the housing 202, the enclosure cap 210 can have a corresponding circular shape. The enclosure cap 210 can have a generally dome-like appearance with a circular or round downward depending sidewall 220 and can generally be set or installed atop of the uppermost circular rim 209 of the canister-like housing 202.

To exhaust the air which is heated by the electronics enclosed in the interior 208 of the enclosure housing 202, the enclosure cap 210 can be configured to include one or more vents that facilitate the chimney effect. To form the vents, the cap 210 can include one or more offset vent panels 212. To accommodate the circular shape of the cap, the vent panels 212 are formed as various arcs or segments of the circular sidewall 220 that protrude outwardly. The individual vent panels 212 are separated from one another by one or more indentations 214 that are formed into the circular sidewall 212. When the enclosure cap 210 is positioned on the top end 204 of the enclosure housing 202, the vent panels 212 are offset with respect to and spaced apart from the upper rim 209 of the housing thereby providing clearances 216 between the vent panels and the housing sidewall. As described above, the clearances 216 establish communication between the interior 208 of the housing 202 and the surrounding environment to allow hot air rising in the housing to escape therefrom. Screens, mesh or similar features can be included to prevent foreign objects from entering the interior via the clearances.

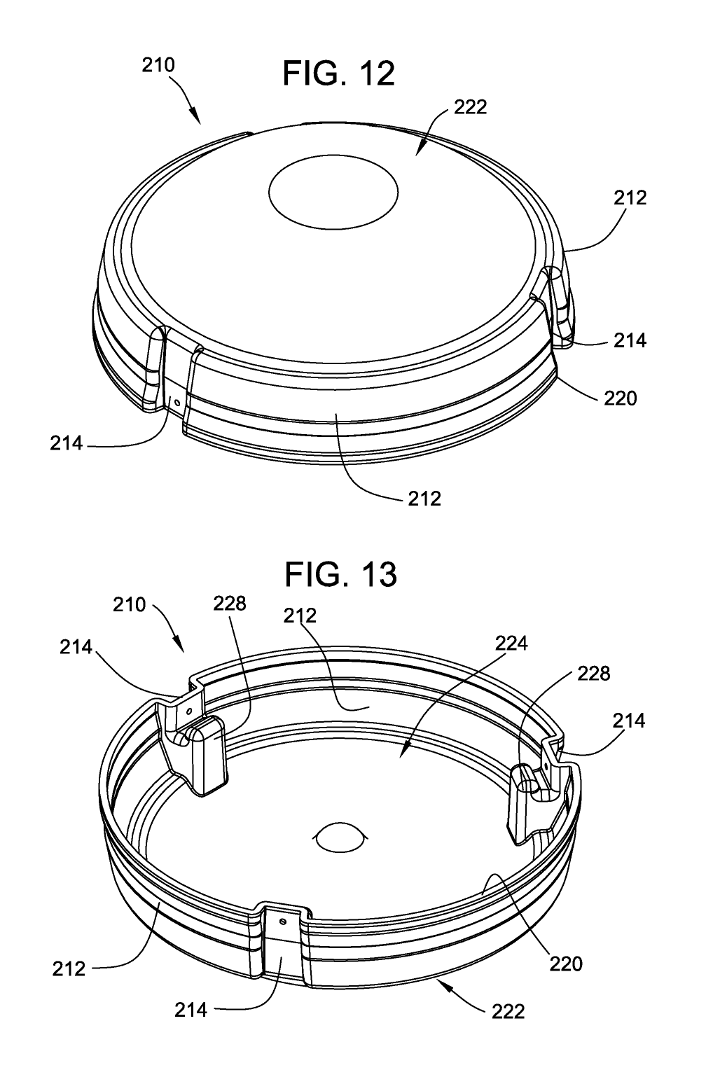

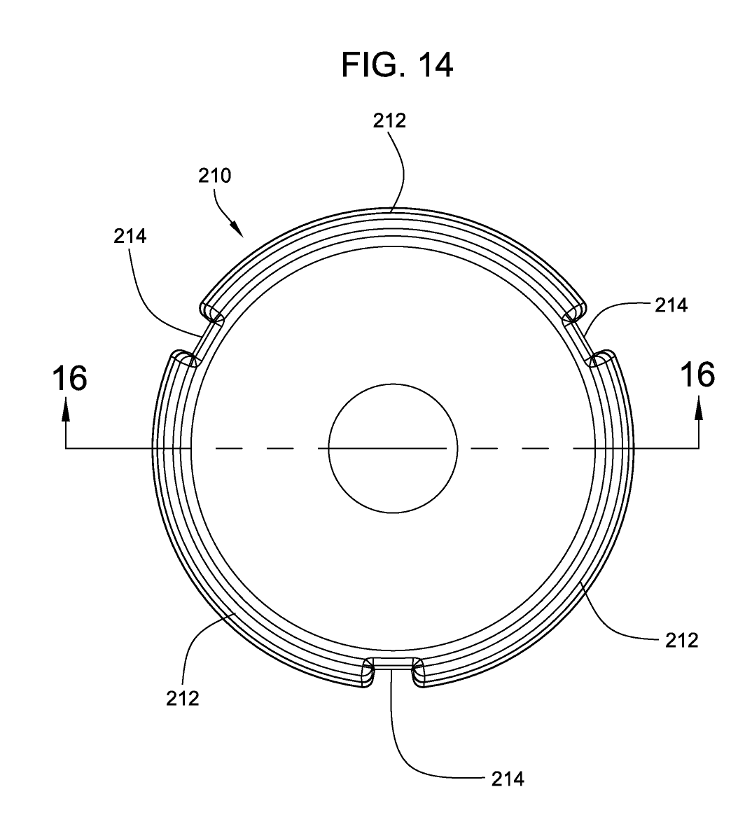

Referring to FIGS. 12, 13, and 14, the circular enclosure cap 210 can have a generally dish-like or bowl-like shape with the round or circular sidewall 220 providing its height. The cap 210 can include an exterior surface 222 that provides in part the rounded, dome-like appearance and an interior surface 224 that, as described below, may be contoured or shaped to assist in venting of the heated air. When the cap 210 is installed on the pedestal housing, the exterior surface 222 will be directed upwardly and exposed to the environment while the interior surface 224 will be exposed to the interior. Additionally, the indentations 214 separating the vent panels 212 can correspond in location with and can even provide in part one or more inwardly directed bosses 228 which, when the cap is positioned on top of the housing, can rest or sit atop of the uppermost rim.

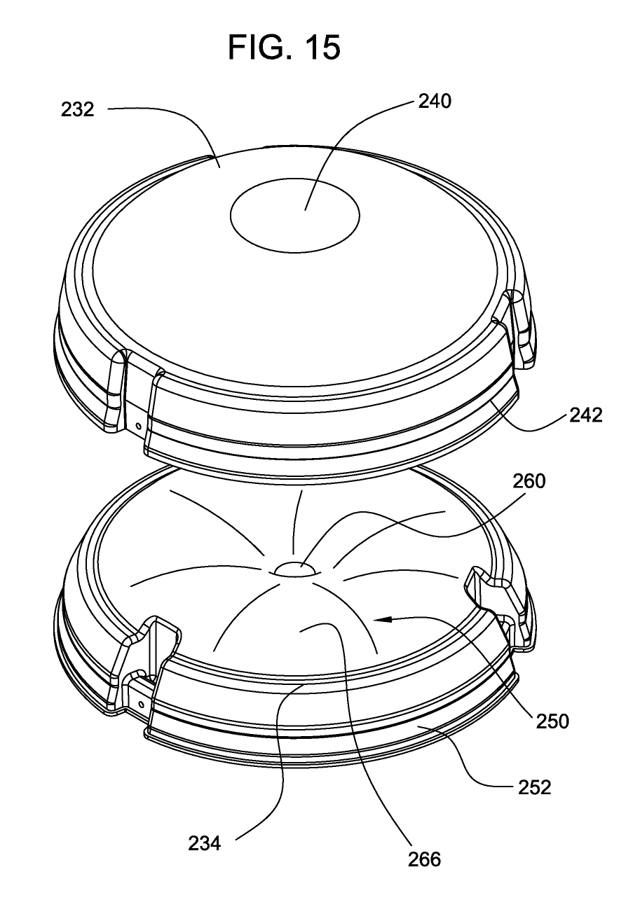

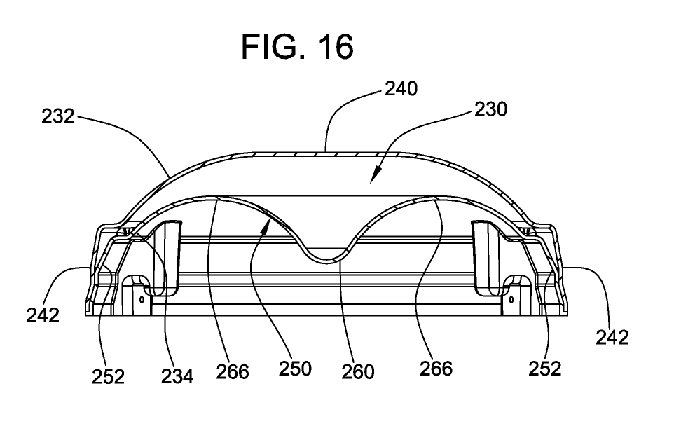

Referring to FIGS. 15 and 16, in an aspect of the disclosure, to buffer or insulate the interior of the enclosure from being heated by solar radiation impinging upon the exterior surface of the enclosure cap 210, the present embodiment of the cap can be formed as a hollow structure with an internal chamber or air gap 230 substantially enclosed within the cap structure. In the illustrated embodiment, the cap 210 can include an upper shield plate 232 and a lower guide plate 234 that are joined together and in between which is provided the air gap 230. The upper shield plate 232 corresponds to the dome-like exterior surface 222 of FIG. 12 while the lower guide plate 234 corresponds to the contoured inner surface 224 of FIG. 13. Both the upper shield plate 232 and the lower guide plate 234 may have an overall circular shape corresponding to the circular shape of the enclosure cap 210.

The upper guide plate 232 can have a rounded or humped central portion 240 that provides a slight, upwardly directed dome and a first depending peripheral wall 242 that extends downwardly from the central portion. In the illustrated embodiment, the peripheral wall 242 is circular. The lower guide plate 234 can also have a central portion 250 and a second depending peripheral wall 252 extending downwardly. When the upper shield plate 232 is joined to the lower guide plate 234, as illustrated in FIG. 16, the first and second depending peripheral walls 242, 252 extend generally coextensively and adjacently with each other such that the upper shield plate 232 appears to receive and retain the lower guide plate 234. In various embodiments, the depending peripheral walls can be intimately joined about the circular circumference to thoroughly enclose and seal the internal air gap.

The contoured central portion 250 of the lower guide plate 234 arcs or curves inwardly from the peripheral side 252 toward a centrally located drooping point 260 proximate the radial center of the circular enclosure 210. The drooping center point 260 forms a cusp that is directed downwardly and away from the central portion of the upper shield plate 232. The air gap 230 is thereby formed between the central portions 240, 250 of the upper shield plate 232 and the lower guide plate 234 which are directed away and spaced apart from each other. When the hollow enclosure cap 210 is installed on the housing 202 as illustrated in FIG. 11, the upper shield plate 232 can deflect some of the impinging radiation from the sun back to the environment. The lower guide plate 234 separates the air gap 230 from the interior 208 of the housing so that the air gap is positioned to buffer or further insulate the interior. In various other embodiments, the air gap can be completely sealed from the interior and the surrounding environment, can be slightly vented to the environment, and/or can be in communication with the interior via one or more smaller holes disposed through the lower guide plate.

In another aspect of the disclosure, to assist in venting air from the interior, the contoured central portion 250 provides the lower guide plate 234 with a vault-like appearance including a curved arch 266 that arcs from the depending peripheral wall 252 to the drooping center point 260. The arch 266 can extend about or around the drooping center point 260 so as to form the shape of a torus that has been planed in half. When the enclosure cap 210 is installed on the housing as illustrated in FIG. 11, the drooping center point 260 is directed downwardly toward the interior and the annularly extending arch 266 is generally directed upwards. Heated air indicated by arrows 272 rising upwards in the housing 202 will encounter the contoured lower guide plated 234 and can be directed by the arch 266 toward the vent panels 212 and back down and out the clearance 216. Thus, the contoured lower guide plate 234 can function to deflect or direct hot air out the top end of the enclosure to facilitate the chimney effect. The circular enclosure cap can be made of any suitable material, such as plastic, and can be manufactured by any suitable process, including the double-walled blow molding process described above. Additionally, the circular enclosure cap can be formed as a monolithic, single piece part or component.

Accordingly, the invention provides a cap for an electronics enclosure that is designed with beneficial thermal control features. For example, in an embodiment, the enclosure cap can be hollow and include an air gap that assists in insulating the interior of the enclosure from solar radiation. In another embodiment, the interior surface of the enclosure cap can be contoured so as to direct heated air rising in the interior of the enclosure toward one or more vent panels for exhaustion to the environment. In a preferred embodiment, the enclosure cap can be a monolithic or single piece design and can be produced by a thermoplastic blow molding process.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

1. A cap for an electronic enclosure comprising:
an upper shield plate including a generally planar central portion and a first depending peripheral wall;
a lower guide plate including a contoured central portion and a second depending peripheral wall;
wherein the upper shield plate and lower guide plate are joined such that the first depending peripheral wall and the second depending peripheral wall are in adjacent contact and the planar central portion and the contoured central portion are partially spaced apart to provide an air gap.

2. The cap of claim 1, wherein the adjacent first and second depending peripheral walls include an offset vent panel.

3. The cap of claim 2, wherein the cap is generally square and the adjacent first and second depending peripheral walls include four interconnected, orthogonally arranged, sides.

4. The cap of claim 3, wherein the contoured central portion includes four arch-like lobes, each lobe curving from one of the four interconnected sides to intersect at a drooping center point.

5. The cap of claim 4, wherein the contoured central portion includes four troughs, each trough extending from one of the four corners of the cap to the drooping center point.

6. The cap of claim 1, wherein the cap is circular.

7. The cap of claim 1, wherein the cap is comprised of thermoplastic material.

8. The cap of claim 7, wherein the cap is of a monolithic or single piece construction.

9. The cap of claim 8, wherein the cap is produced by a blow-molding process.

10. An outdoor, pedestal style electronic enclosure comprising:
an upright, elongated housing defining an interior for storing electronics and having an opened top end; and
an hollow enclosure cap installed at the top end of the housing, the hollow enclosure cap defining an air gap substantially separated from and insulating the interior.

11. The electronic enclosure of claim 10, wherein the hollow enclosure cap includes a vent panel spaced apart from an upper rim of the housing to provide a clearance venting the interior to the outside environment.

12. The electronic enclosure of claim 11, wherein the hollow enclosure cap is a box-like structure including four orthogonal, interconnecting sides, a dome-like exterior surface, and a contoured interior surface.

13. The electronic enclosure of claim 12, wherein the air gap is between the dome-like exterior surface and the contoured interior surface.

14. The electronic enclosure of claim 11, wherein the hollow enclosure cap includes an upper shield plate joined to a lower guide plate, the air gap defined between the upper shield plate and the lower guide plate.

15. The electronic enclosure of claim 14, wherein the upper shield plate is exposed to the environment and the lower guide plate is exposed to the interior when the cap is installed on the housing.

16. The electronic enclosure of claim 15, wherein the lower guide plate includes a contoured central portion having one or more arch-like lobes curving from a periphery proximate the vent panels downwardly to a drooping center point depending towards the interior of the enclosure.

17. The electronic enclosure of claim 16, wherein the one or more arch-like lobes are separated from each other by one or more troughs depending towards the interior of the enclosure.

18. The electronic enclosure of claim 10, wherein the housing is cylindrical and the enclosure cap is circular.

19. The electronic enclosure of claim 10, wherein the hollow enclosure cap is comprised of thermoplastic material.

20. The electronic enclosure of claim 19, wherein the hollow enclosure cap is a monolithic structure produced by a blow molding process.

21. A method of heat compensation for an upright electronic pedestal style enclosure comprising:
providing an elongated, upright housing including an interior space and having an opened top end;
installing at the open top end an enclosure cap, the enclosure cap including a dome-like upper shield plate exposed to the exterior, a contoured lower guide plate exposed to the interior, and an air gap delineated between the upper shield plate and lower guide plate, the enclosure cap further including one or more vent panels that are offset with respect to an upper rim of the opened top end to provide a clearance;
cooling the interior by directing heated air rising upwards in the housing toward the clearance via the contoured guide plate; and
insulating the interior from solar induced heat impinging on the shield plate via the air gap.
